(19) United States
(12) Patent Application Publication
(10) Pub. No.: US 2012/0298031 A1
(43) Pub. Date: Nov. 29, 2012

(54) DEVICE FOR SINGLE-CRYSTAL GROWTH AND METHOD OF SINGLE-CRYSTAL GROWTH

(75) Inventors: Toshimitsu Ito, Tsukuba-shi (JP); Yasuhide Tomioka, Tsukuba-shi (JP); Yuji Yanagisawa, Tsukuba-shi (JP); Isamu Shindo, Hokuto-shi (JP); Atsushi Yanase, Noda-shi (JP)

(73) Assignees: CRYSTAL SYSTEMS CORPORATION, Yamanashi (JP); NATIONAL INSTITUTE OF ADVANCED INDUSTRIAL SCIENCE AND TECHNOLOGY, Tokyo (JP)

(21) Appl. No.: 13/521,524

(22) PCT Filed: Dec. 28, 2010
(86) PCT No.: PCT/JP2010/073699

§ 371 Date: Jul. 11, 2012

(30) Foreign Application Priority Data
Jan. 15, 2010 (JP) 2010-006894

(51) Int. Cl. C30B 13/24

(52) U.S. Cl. 117/50; 117/222

(57) ABSTRACT

[Technical Problem]

It is an object to provide a device for a single-crystal growth and a method of a single-crystal growth in which even when materials that are different in, for example, a melting point or a diameter are to be grown, the conditions for the stable growth of a single crystal can be obtained and a high-quality single crystal having a desired diameter can hence be grown. In addition, the device and the method have a reduced fluctuation of heating intensity to facilitate a crystal growth.

[Solution of Problem]

A device for a single-crystal growth is provided with a raw material rod (14) that is supported by an upper crystal driving shaft (8), a seed crystal rod (16) that is supported by a lower crystal driving shaft (12), and a heating means, and a contact part of the raw material rod (14) with the seed crystal rod (16) is heated with a heating means to form a melting zone (18) and grow a single crystal. The device is characterized in that the heating means is configured by a plurality of rectangular beams produced by lasers (2a, . . . 2e) which emit a laser light having the equivalent irradiation intensity and by an optical means, the heating means being disposed in a circumferential direction of the melting zone (18).

### TECHNICAL FIELD

The present invention relates to a device for a single-crystal growth and a method of a single-crystal growth in which a part of a material in the shape of a rod is irradiated with a laser light to form a melting zone and a single crystal is grown. More specifically, the present invention relates to an improvement of a stable growth of a crystal.

### BACKGROUND ART

A floating zone melting device of an infrared ray lamp concentration heating type that has been used widely in general has the following advantages and is used widely for a growth of a single crystal and a research of phase equilibrium:
(i) A sample material can be molten without using a crucible.
(ii) An atmosphere gas can be selected freely.
(iii) A single-crystal growth of a wide variety of compositions can be carried out using a floating zone method.
(iv) A research of phase equilibrium can be carried out based on a floating zone slow cooling method.
(v) A high temperature can be easily obtained by a comparatively less electric power.

However, in the case of a crystal growth based on a floating zone method of a conventional infrared ray lamp concentration heating type, a light collecting property is degraded and a solid part other than a floating zone is heated unfortunately. Consequently, a melt penetrates from a floating zone to a solid part and a melt spills out, whereby a crystal growth is not stable unfortunately.

The reason of this problem will be described in the following from a point of view of a structure of a device and rod shaped material.

In the case of a crystal growth based on a floating zone method of a conventional lamp type, a light of an infrared ray lamp such as a halogen lamp and a xenon lamp is reflected by an ellipsoidal mirror to form a light collecting region, a lower part of a raw material rod that is suspended vertically from an upper side and an upper side of a seed crystal that is set on the lower side are applied to the light collecting region to heat and melt those, the both is coupled to each other to form a floating zone, and a raw material rod and a seed crystal or an infrared ray light collecting region from a lamp is moved to melt a raw material and to grow a single crystal. A filament is used as a light emitting part of an infrared ray lamp for instance in the case of a halogen lamp. Consequently, a size and a temperature distribution of a light collecting region are varied by a shape and a size of a filament and an eccentricity and a size of an ellipsoidal mirror and are several times to several ten times of a size of a filament in general. A maximum light density part is formed at the central part and a light density is reduced to periphery smoothly.

On the other hand, in the case in which a single crystal of a compound that is corresponded to a wide variety of purposes is grown, a raw material powder of a composition of the purpose is prepared at a predetermined ratio and molded and sintered in a round rod shape. The melting property is an incongruent melting in general. That is, a partial melting is started in accordance with a rise of a temperature and the entire is molten perfectly after a temperature becomes higher. In the case in which a material having such a characteristic is processed in a rod shape and a material in a rod shape is inserted vertically from the upper side into a light collecting region, the material is molten completely in the maximum temperature part, and a peripheral part is partially molten since a temperature is lower. And a solid part in which a partial melting is not yet started coexists vertically circumferentially. In such a state, a melt that is formed is held by a part that has partially molten and expands the part. Consequently, the shape and the size of the part are not stable and a stable shape of a melting region is difficult as a result. Therefore, it is extremely difficult to grow a high quality crystal that is enabled by stably continuing a melting and a deposition of a raw material.

A shutter that is configured to partially shut a path of a light that is reflected has been used as a countermeasure of the problem in order to make a temperature gradient steep in a vertical direction.

In addition, a wide variety of countermeasures for forming a stable melting region by making a temperature gradient of a melting part and others steep and by minimizing a formation of a solid-liquid coexistence region to the utmost limit. However, a satisfactory result cannot be obtained in many cases.

On the other hand, a melting point and a diameter of a material to be grown are varied in accordance with an intended purpose and cannot be decided unambiguously. Consequently, it is preferable that a heating that is most suitable for a diversity of a material can be implemented as a heating means. A device of a low cost for a single-crystal growth in which a light collecting property and a usability are excellent has been requested.

As a device for a single-crystal growth, the following techniques have been proposed for instance.

The Patent Literature 1 discloses a growth of a single crystal in which a laser light source that directly irradiates a raw material rod is a main heating source and a resistance heating element is used as an auxiliary heating source to implement an optimization and reproducibility for the conditions of a growth of a single crystal.

For a device for a single-crystal growth that is disclosed in the Patent Literature 2, after a laser light is made to be a thick parallel light in a columnar shape in order to irradiate the whole circumference of a floating zone with a uniform laser light of high intensity, the parallel light is made to be a light in a hollow cylindrical shape, and the light in a hollow cylindrical shape is reflected by a reflection mirror that is disposed around a transparent quartz tube and a melting zone is irradiated with the light.

For a device for a single-crystal growth that is disclosed in the Patent Literature 3, a laser light is used as a heating source and a rotating magnetic field is applied to a melting zone in order to grow a single crystal.

A wide variety of proposals have been carried out as described above. However, a constituent element such as a magnetic field application means and an auxiliary heating means is required for a conventional example. In addition, a structure is complicated and the maintenance and an inspection are troublesome, whereby a satisfactory result cannot be obtained.

### PRIOR ART DOCUMENTS

### Patent Literature

### [Patent Literature 1]

Japanese Patent Application Laid-Open Publication No. 2002-68882

### [Patent Literature 2]

Japanese Patent Application Publication No. 3723715

### [Patent Literature 3]

Japanese Patent Application Laid-Open Publication No. 2007-145629

### SUMMARY OF INVENTION

### Problems to be Solved by the Invention

An object of the present invention is to provide a device for a single-crystal growth and a method of a single-crystal growth in which a single crystal of a high quality can be grown stably by using a rectangular laser light independently of a melting point and a diameter of a material to be grown and even in the case of an incongruent melting.

Another object of the present invention is to provide a device for a single-crystal growth and a method of a single-crystal growth in which a difference in a diameter of a material and an adjustment of a width of a melting zone can be accepted by an easy structure at a low cost.

### Means for Solving the Problems

A device for a single-crystal growth in accordance with the present invention for achieving the above purpose is provided with a raw material rod that is supported by an upper crystal driving shaft, a seed crystal rod that is supported by a lower crystal driving shaft, and a heating means that is configured to heat a contact part of the raw material rod with the seed crystal rod, wherein the contact part of the raw material rod with the seed crystal rod is molten with a heating means to form a melting zone that is a single-crystal growth part and to grow a single crystal, wherein the heating means is configured by a plurality of laser light sources that emit a laser light having the equivalent irradiation intensity and a plurality of optical means that are disposed in connection to the laser light sources and that irradiate the melting zone with a laser light that has been emitted from the laser light source and is disposed in a circumferential direction of the melting zone, and

the optical means is configured in such a manner that a spot shape of the laser light to the melting zone is in a rectangular shape in which a laser intensity distribution in a radial direction and in an axial direction for the melting zone is generally uniform.

For a device for a single-crystal growth in accordance with the present invention, it is preferable that the optical means is configured in such a manner that widths in a radial direction and in an axial direction of the melting zone that are formed in a rectangular shape for the laser light can be arbitrarily varied in accordance with a variation of a diameter of the raw material rod or the seed crystal rod.

For a device for a single-crystal growth in accordance with the present invention, it is preferable that the laser light source is a laser diode.

For a device for a single-crystal growth in accordance with the present invention, it is preferable that a homogenizer which makes an emitted light intensity uniform is used as the optical means.

For a device for a single-crystal growth in accordance with the present invention, it is preferable that a light pipe is used as the optical means.

For a device for a single-crystal growth in accordance with the present invention, a rectangular fiber can also be used as the optical means as substitute for a light pipe.

For a device for a single-crystal growth in accordance with the present invention, it is preferable that the laser light sources of an odd number are disposed.

For a device for a single-crystal growth in accordance with the present invention, it is preferable that the laser light sources of an odd number equal to or larger than 3 are disposed.

A method of a single-crystal growth in accordance with the present invention is characterized in that a contact part of a raw material rod that is supported by an upper crystal driving shaft with a seed crystal rod that is supported by a lower crystal driving shaft is heated and molten to form a melting zone that is a single-crystal growth part and to grow a single crystal, wherein a laser intensity distribution in a radial direction and in an axial direction for the melting zone is in a generally uniform rectangular shape, and the melting zone is irradiated from a circumferential direction of the melting zone with a plurality of laser lights having the equivalent irradiation intensity.

### Advantageous Effects of Invention

By a device for a single-crystal growth in accordance with the present invention, a laser light is introduced to a melting zone without a scattering in a midstream, the whole circumference of a melting zone is heated uniformly in an efficient fashion, a solid part other than a melting zone is held to be at a low temperature, a solid part through which a liquid phase penetrates from a melting zone is reduced, and a stable melting zone can be formed. In addition, since distribution in an axial direction of the intensity of a laser light is in a generally uniform rectangular shape and a rising and a falling of the intensity are steep, a penetration (a partial melting) to a solid part is reduced and a melt does not spills out onto a solid part, whereby a good quality of a single crystal can be grown in a stable manner.

Moreover, a position of an interface between a melting liquid phase and a solid phase is generally corresponded to a position of a rising and a falling of an intensity distribution of a laser light. Consequently, a vertical width of a melting zone can be easily adjusted to be a necessary size by a vertical width of a laser beam spot that is a focal point diameter of a laser light.

Moreover, a width in a radial direction of a laser beam spot can be almost equal to or larger than a diameter of a raw material rod or a grown crystal. Consequently, the conditions of a stable growth of a single crystal are achieved even in the case in which a diameter of a material in a rod shape is varied, and a growth of a single crystal of a material in a rod shape having an arbitrary diameter can be implemented.

Moreover in accordance with the present invention, a material is irradiated with a laser light directly without a magnetic field application means or an auxiliary heating means. Consequently, the device is very user-friendly and the maintenance and an inspection can be easily carried out.

Moreover, a light collecting property of a laser light is excellent, whereby a heating efficiency is high advantageously.

Moreover, since a price of a semiconductor laser is tended to be lower, it can be expected that a price of a device is lowered, thereby making a contribution to a cost cutting.

### BRIEF DESCRIPTION OF THE DRAWINGS

FIG. 1 is a schematic plan view showing a device for a single-crystal growth in accordance with an embodiment of the present invention.

FIG. 2 is a schematic view showing a relationship between a device for a single-crystal growth in accordance with an embodiment of the present invention shown in FIG. 1 and a collected light intensity distribution in an axial direction of a laser light.

FIG. 3 is a schematic view showing a relationship between a device for a single-crystal growth in which a conventional halogen lamp heating system is adopted and a collected light intensity distribution in an axial direction.

FIG. 4 is a schematic view showing a relationship between a device for a single-crystal growth in which a conventional Gaussian distribution laser heating system is adopted and a collected light intensity distribution in an axial direction.

FIG. 5 is a schematic view showing a relationship between a device for a single-crystal growth in accordance with an embodiment of the present invention and a collected light intensity distribution in a radial direction of a laser light.

FIG. 6 is a diagram of an optical system showing an operation of a light pipe that is adopted in an embodiment of the present invention.

FIG. 7(A) is a photograph of a melting zone in the case in which a laser furnace in accordance with an embodiment of the present invention is adopted. FIG. 7(B) is a photograph of the crystal rod.

FIG. 8(A) is a photograph of a melting zone in the case in which a conventional halogen lamp furnace is adopted. FIG. 8(B) is a photograph of the crystal rod.

FIG. 9 is a schematic plan view showing a device for a single-crystal growth in accordance with another embodiment of the present invention.

FIG. 10 is a diagram of an optical system showing a device for a single-crystal growth in accordance with another embodiment of the present invention in which an array semiconductor laser is used as a laser light source.

FIG. 11 is a schematic perspective view showing a substantial part of a device for a single-crystal growth in accordance with another embodiment of the present invention.

FIG. 12 is a structural diagram of an optical fiber that is provided with a function almost equivalent to that of a light pipe that is adopted in an embodiment of the present invention.

FIG. 13(A) is a schematic cross sectional view showing an example of a case in which a width of a rectangular beam is adjusted. FIG. 13(B) is a schematic cross sectional view showing another example of a case in which a width of a rectangular beam is adjusted.

### DESCRIPTION OF EMBODIMENTS

A device for a single-crystal growth with a laser light of a floating zone system in accordance with the present invention is mainly configured by a main body that is provided with a single-crystal growth space that is configured to grow a single crystal from a raw material rod and a seed crystal rod, a personal computer, a liquid crystal display, a power supply unit, an electrical leakage breaker, and a floating zone (FZ) control device that is configured to control an output of a semiconductor laser of a high output of a fiber coupling type and a movement speed and a rotation speed of an upper crystal driving shaft and a lower crystal driving shaft.

The main body is provided with a television camera that is configured to observe a heated part on a real-time basis. The semiconductor laser of a high output of a fiber coupling type to which an electrical power is supplied from a constant-voltage constant-current direct-current power supply is connected to the main body via an optical fiber, and irradiates a material that is disposed in the single-crystal growth space with a laser light. Moreover, the semiconductor laser of a high output of a fiber coupling type is incorporated into the Peltier element, and a temperature based on the Peltier element is controlled by a Peltier controller. Moreover, the main body is connected to a gas controller that is configured to flow an atmosphere gas in the single-crystal growth space and a circulation type liquid cooling apparatus that is configured to cool a heated part of the main body and the Peltier element.

The present invention will be described in the following while an emphasis is placed on a substantial part around a floating zone (a melting zone).

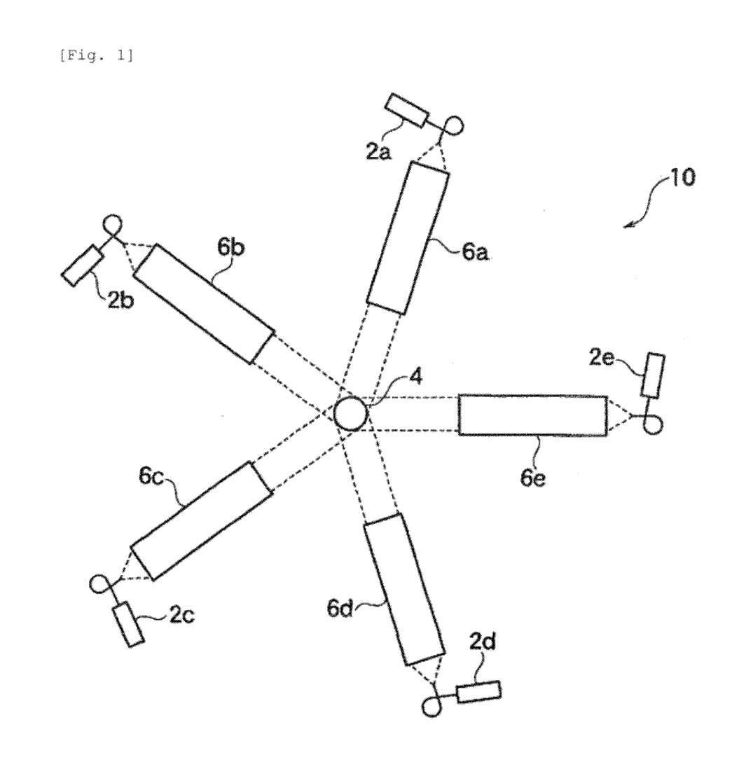

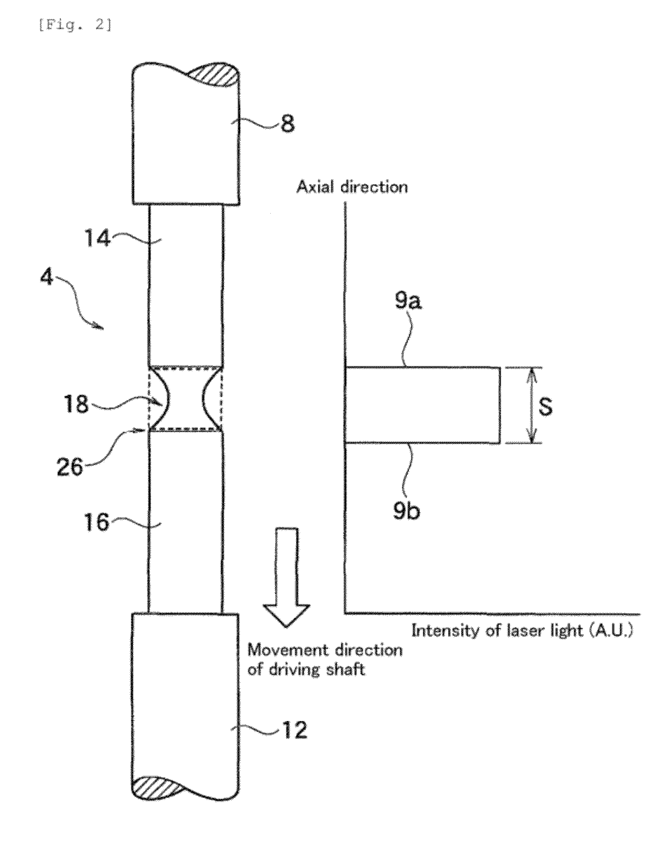

FIG. 1 is a schematic plan view showing a device for a single-crystal growth in accordance with an embodiment of the present invention. FIG. 2 is a schematic view showing a relationship between a device for a single-crystal growth in accordance with an embodiment of the present invention shown in FIG. 1 and a intensity distribution in an axial direction of a laser light for a melting zone that occurs in the case in which a material in a rod shape is irradiated with a laser light.

For a device 10 for a single-crystal growth in accordance with an embodiment of the present invention, the five semiconductor lasers 2a, 2b, 2c, 2d, and 2e of a high output of a fiber coupling type are used as a laser light source. The semiconductor lasers 2a, 2b, 2c, 2d, and 2e are disposed around a material 4 in a rod shape at generally even intervals. It is not necessary that the semiconductor lasers 2a, 2b, 2c, 2d, and 2e are disposed at even intervals in the case in which an optical fiber is used. Rather, it is necessary that the optical systems such as a homogenizer described later are disposed at even intervals. The number of laser light sources that are configured by semiconductor lasers is not restricted to five. However, it is preferable that laser light sources of an odd number are disposed as described later. In particular, in the case in which the laser light sources of an odd number equal to or larger than 3 are disposed, a desired purpose of a homogenization of heating can be achieved sufficiently.

The device 10 for a single-crystal growth is configured by a heating means, an upper crystal driving shaft 8 and a lower crystal driving shaft 12 that support a material 4 in a rod shape. The heating means is configured by the semiconductor lasers 2a, 2b, 2c, 2d, and 2e of a high output of a fiber coupling type that is provided with an equivalent irradiation intensity and the light pipes (optical means) 6a, 6b, 6c, 6d, and 6e as a homogenizer that forms a light source in a rectangular shape by reflecting a light at a side face of a polygonal column or a pyramid more than once. The material 4 in a rod shape is configured by a raw material rod 14 and a seed crystal rod 16. Moreover, the material 4 in a rod shape is contained in a transparent quartz tube not shown, and the quartz tube is filled with an atmosphere gas that is suitable for growing a single crystal.

The raw material rod 14 is supported to the upper crystal driving shaft 8 that moves upward and downward and rotates, and the seed crystal rod 16 is supported to the lower crystal driving shaft 12 that moves upward and downward and rotates. Moreover, the upper crystal driving shaft 8 and the lower crystal driving shaft 12 are rotated in an opposite direction from each other.

The light pipes 6a, 6b, 6c, 6d, and 6e as a homogenizer shown in FIG. 1 are pipes in which a cross sectional surface is formed in a rectangular shape, and a reflecting face is formed in which a laser light can be reflected in an inner face of a pipe. Moreover, the light pipes 6a, 6b, 6c, 6d, and 6e functions as a homogenizer that is configured to form a laser light in a rectangular shape by reflecting and transmitting a laser light in an inner face of a pipe and to uniform an intensity distribution. The light pipes 6a, 6b, 6c, 6d, and 6e are arranged in the same plane in a circumferential direction of the upper crystal driving shaft 8 and the lower crystal driving shaft 12.

A material is irradiated perpendicularly to an axis line that connects the upper crystal driving shaft 8 and the lower crystal driving shaft 12 with a light from the semiconductor lasers 2a, 2b, 2c, 2d, and 2e.

In the present invention, by disposing the light pipes 6a, 6b, 6c, 6d, and 6e as an optical means, a laser intensity distribution in a radial direction and in an axial direction of the melting zone 18 can be in a generally uniform rectangular shape, and a width of the laser intensity distribution in a rectangular shape can be varied arbitrarily.

The device 10 for a single-crystal growth in accordance with an embodiment of the present invention is configured as described above. The operation of the device 10 for a single-crystal growth in accordance with an embodiment of the present invention will be described in the following.

In the following description, an FZ apparatus that is configured to form a melting zone by a laser light source in accordance with the present invention will be described as a laser furnace, and an FZ apparatus that is configured to form a melting zone by using a halogen lamp and a spheroidal mirror in the conventional way will be described as a halogen lamp furnace.

In the present invention, in FIG. 2, a contact part of the raw material rod 14 with the seed crystal rod 16 is irradiated with a laser light in a vertical direction to an axis line, and the melting zone 18 is formed by making a laser intensity distribution in a radial direction and in an axial direction be in a generally uniform rectangular shape. A single crystal is grown continuously in the melting zone 18 by moving both of the upper crystal driving shaft 8 and the lower crystal driving shaft 12 downward.

A diameter of the raw material rod 14 that has been adopted and a diameter of the seed crystal rod 16 that has been adopted are 5 mm.

A collected light intensity distribution of a laser light in a circumferential direction of the material 4 in a rod shape in accordance with an embodiment of the present invention will be described in the first place.

The operating principle of the present invention has already been applied, and is equivalent to an operation that is disclosed in detail in Japanese Patent Application Laid-Open Publication No. 2009-040626 publicly known (hereafter referred to as a prior application). For an effect that is related to a laser intensity distribution in a circumferential direction based on the operating principle, the equivalent effect can be obtained in the case in which alight intensity distribution is the Gaussian distribution like the prior application and in the case in which a light intensity distribution is a uniform distribution like the embodiment of the present invention. Consequently, the essential points thereof will be described in this specification.

For the present invention, the following two conditions (1) and (2) are essential for the uniformity in an intensity distribution in a circumferential direction:
(1) A plurality of light sources are used, in particular, light sources of an odd number are used similarly to the prior application.
(2) A width of a uniform beam is made to be larger than a material in a rod shape.

In other words, a uniformity degree of the irradiation intensity is improved in general by using a plurality of light sources as described in (1) and is raised in proportion to that in the case in which the simultaneous outputs are carried out. In accordance with a simulation, in the case in which the number of light sources is larger, a uniformity degree of the irradiation intensity in a circumferential direction of the material in a rod shape is tended to be increased. A uniformity degree for an odd number is improved as compared with that for an even number. Consequently, it is preferable to use a plurality of light sources, in particular, light sources of an odd number equal to or larger than 3.

Moreover, in a realistic growth of a crystal a material is shifted from a central axis in a practical sense by the reasons of a misalignment of an attachment, a curvature of a raw material rod, and an eccentricity caused by a contact of a raw material rod and a crystal. Therefore, an influence of a misalignment from a central axis can be deleted completely in the case in which the material in a rod shape is within a beam width as described in (2) by making a width of a uniform beam larger than the material in a rod shape.

As described in the prior application, even in the case in which a beam width is larger in the case of the Gaussian distribution, the irradiation intensity is tended to be decreased in the case in which the material in a rod shape is shifted from a central axis.

In the case in which the material 4 in a rod shape is irradiated with a laser light that has been emitted from each of the semiconductor lasers 2a, 2b, 2c, 2d, and 2e of a fiber coupling type shown in FIG. 1, an intensity distribution of a surface of the material 4 in a rod shape is varied normally by a sine function at a part which is irradiated with a light from each laser, and becomes zero at a part which is not irradiated with a light from each laser. The entire intensity distribution of a surface of the material 4 in a rod shape that is obtained as the sum of them is a pulsating periodic function in which an almost maximum part of a sine function of a 360-degree cycle is repeated.

An intensity becomes minimal at a junction of this repetition. An angle of a junction is corresponded to an angle in which an intensity of a laser light with which a material is irradiated from a direction becomes zero from a finite value (an angle that enters a shadow) and exists at two points to one laser light. A uniformity of an intensity distribution in a circumferential direction is improved in accordance with an increase in the number of laser light sources. In particular, in the case in which the number of laser light sources is an odd number, a minimum angle in an intensity distribution of a light that is created by each of the laser lights does not overlap with each other. Consequently, the number of minimums (repetitions) is double of the number of laser light sources. As a result, a smoothing property of an intensity distribution of a laser light can be improved as compared with the case in which the number of laser light sources is an even number. On the other hand, in the case in which the number of laser light sources is an even number, a minimum angle in an intensity distribution of light that is created by an opposite laser light overlaps with each other. Consequently, the number of minimums (repetitions) is equivalent to the number of laser light sources.

In the next place, a collected light intensity distribution in an axial direction of a laser light of the material 4 in a rod shape will be described in the following.

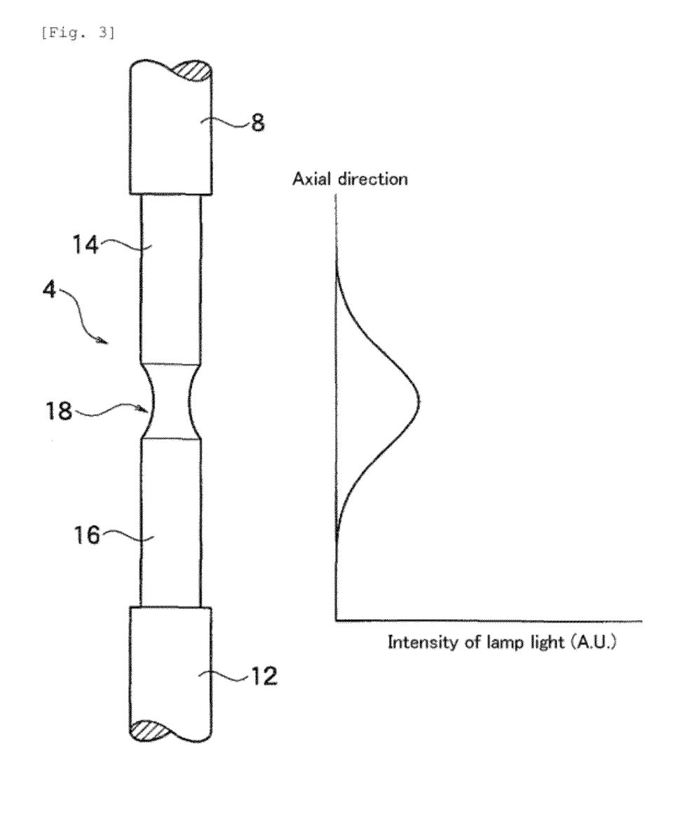

In the first place, the case of a halogen lamp furnace that is a conventional example will be described with reference to FIG. 3. In the case in which an intensity distribution in an axial direction of a light around a melting zone 18 is approximated by the Gaussian distribution, a distribution in which a standard deviation is large is indicated as shown by a graph on the right side of FIG. 3. This intensity distribution is larger than that in the case of a laser furnace that is shown by a graph on the right side of FIG. 2. Consequently, in the case of a halogen lamp furnace, a range of a penetration to the raw material rod 14 is large in an axial direction and the part is expanded, thereby causing a spill onto the seed crystal rod 16.

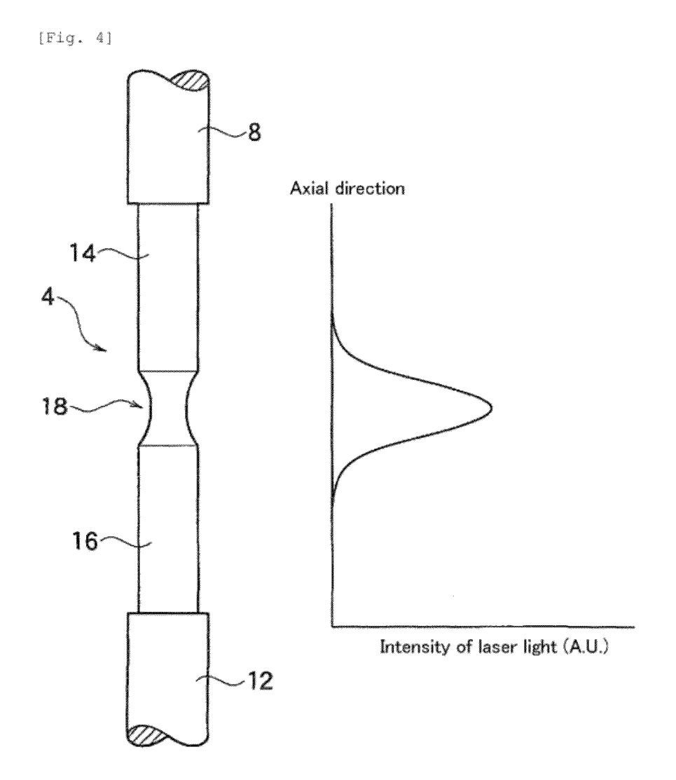

In order to solve the above problem, a configuration has been proposed in which a laser light source and a lens are combined to make a collected light intensity distribution of a laser light to be approximated by the Gaussian distribution in which a standard deviation is small. FIG. 4 shows the configuration. In this case, although an intensity of a laser light is high at a central part of a melting zone as shown by a graph on the right side of FIG. 4, an intensity distribution on the both sides in an axial direction is smooth and insufficient. Consequently, a penetration to the raw material rod 14 occurs, thereby causing a spill onto the seed crystal rod 16. Moreover, the lower crystal driving shaft 12 blocks a light path because of the structure, whereby the uniformity in a circumferential direction is sacrificed unfortunately.

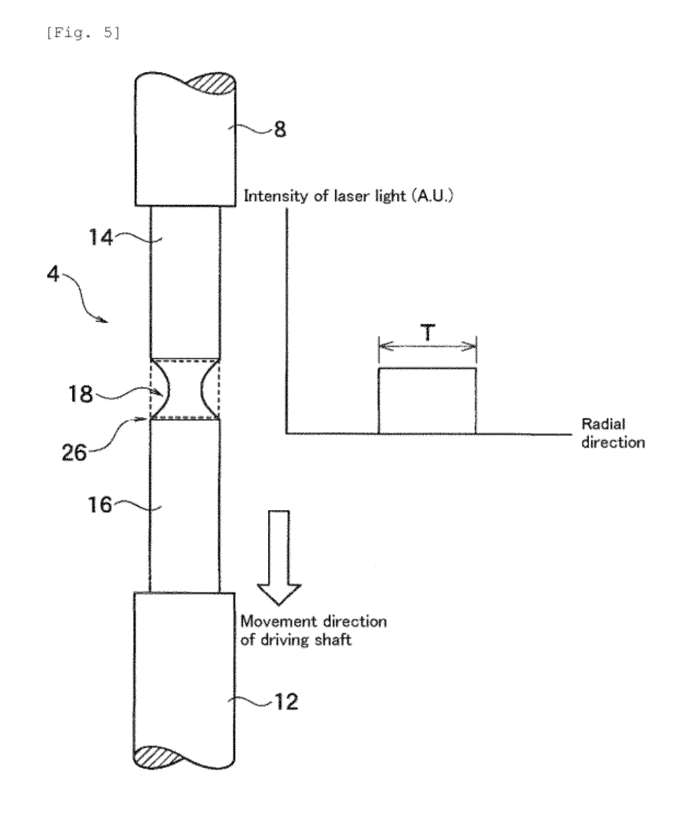

On the other hand, FIG. 2 and FIG. 5 are schematic views showing a collected light intensity distribution of a laser light in an axial direction and in a radial direction in accordance with an embodiment of the present invention.

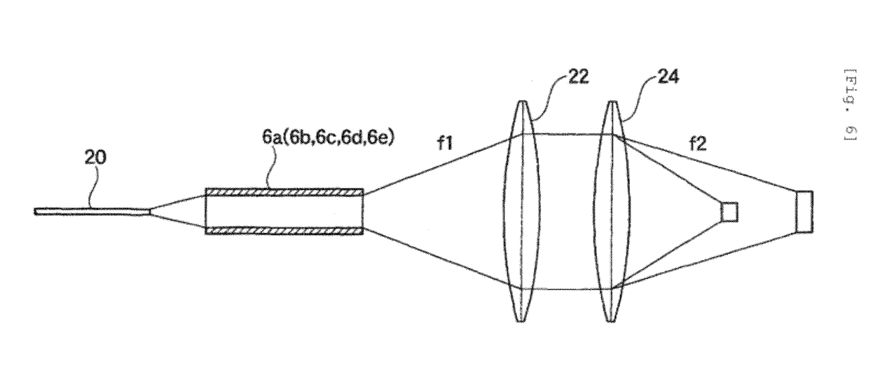

In the first place, the basic operation of the light pipes 6a, 6b, 6c, 6d, and 6e that are used in the present embodiment shown in FIG. 1 will be described with reference to FIG. 6.

The light pipes 6a, 6b, 6c, 6d, and 6e, are pipes in which a cross sectional shape is formed in a rectangular shape as described above, and a reflecting face is formed in which a laser light can be reflected in an inner face of a pipe. Moreover, the light pipes 6a, 6b, 6c, 6d, and 6e functions as a homogenizer that is configured to form a laser light in a rectangular shape by reflecting and transmitting a laser light in an inner face of a pipe and to uniform an intensity distribution.

A laser beam that has been emitted from an optical fiber 20 is reflected in a repetitive manner inside the light pipes 6a, 6b, 6c, 6d, and 6e in which a cross sectional shape is formed in a rectangular shape and is uniformed to be in a rectangular shape. The laser beam is transmitted from the light pipes 6a, 6b, 6c, 6d, and 6e in a radial fashion, is introduced to the collimated lens 22, and is converted into a parallel light in the collimated lens 22. In the next place, the laser beam is collected in a rectangular shape to a material 4 in a rod shape that is an object to be heated by a light collecting lens 24.

For the present invention, it is preferable that a laser diode is used as the laser light source in particular. In the case in which a laser diode is used as the laser light source, a laser wavelength that is suitable in accordance with a laser absorption characteristic of the material 4 in a rod shape can be selected, whereby the extremely efficient heating can be carried out.

As described above, the light pipes 6a, 6b, 6c, 6d, and 6e that are provided with the above function are disposed between the semiconductor lasers 2a, 2b, 2c, 2d, and 2e as a light source and the material 4 in a rod shape. Consequently, a laser light that has been emitted from the semiconductor lasers 2a, 2b, 2c, 2d, and 2e of a high output of a fiber coupling type shown in FIG. 1 is reflected at a side face of a polygonal column or a pyramid of the light pipes 6a, 6b, 6c, 6d, and 6e more than once, makes a spot shape of a laser light to be a rectangular shape as shown by a dotted line in FIG. 2, and forms the spot shape in a contact part of the material 4 in a rod shape. The intensity distribution of a laser light in a rectangular shape is uniform. In the case in which a material is irradiated with the laser light in which the intensity distribution is uniform, a temperature distribution of a melting zone can be close to be uniform.

By this configuration, as shown by a graph on the right side of FIG. 2, the laser intensity distribution of a laser light around the melting zone 18 can be uniformed, and a rising part 9a and a falling part 9b in the axial direction shown in FIG. 2 can be made steep. As a result in the present embodiment, a material can be molten uniformly in the melting zone, a penetration to the upper and lower solid parts can be extremely reduced, and a melt does not spill out onto a solid part, whereby a good quality of a single crystal can be grown.

In the case in which a width T in a radial direction of a beam is equal to or larger than a diameter of the raw material rod 14 in general, a light in a circumferential direction is collected uniformly and a uniformity degree can be maintained to an eccentricity from a central axis, whereby a crystal is grown stably. For the conventional intensity distribution of the Gaussian distribution (see FIG. 3 and FIG. 4), an expanse in an axial direction is ambiguous. As a result, an interface between a melting liquid phase and a solid phase cannot be determined uniquely, and it is difficult to decide the Gaussian distribution of a suitable expanse.

On the other hand in the present invention, since a location of an interface between a melting liquid phase and a solid phase is generally corresponded to a location of a rising part 9a and a falling part 9b of a laser light intensity as described above, a device design for obtaining a melting zone of a desired length and a determination of a condition for growing a crystal can be easily carried out.

It is preferable that the intensity distribution of a laser light is a distribution in a rectangular shape in which a rising part 9a and a falling part 9b in the axial direction is steep from the standpoint of preventing a penetration to the raw material rod 14 and a spill onto the seed crystal rod 16. However, it is not necessary that a central part of the rectangular shape is flat, and any shape can also be adopted.

By the light pipes 6a, 6b, 6c, 6d, and 6e, a size of a width S in an axial direction and a size of a width T in a radial direction shown in FIG. 2 and FIG. 5 can be arbitrarily modified.

As shown in FIG. 6 for instance, in the case in which a collimated lens 22 of a focal point distance f1 is disposed beyond the light pipes 6a, 6b, 6c, 6d, and 6e and a light collecting lens 24 of a focal point distance f2 is disposed further beyond that, when a focal point distance f2 of the light collecting lens 24 is increased, a range of a rectangular can be enlarged. Moreover on the other hand, when a focal point distance f1 of the collimated lens 22 is decreased, a range of a rectangular can be enlarged.

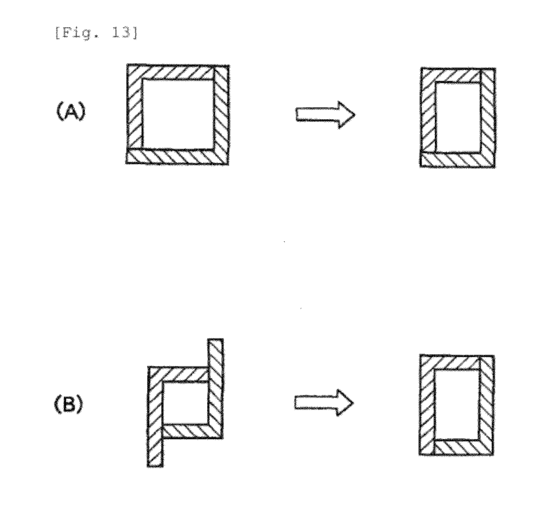

Moreover as shown in FIG. 13(A) and FIG. 13(B), a range of a rectangular spot shape of a laser light can be adjusted by switching a shape of the light pipes 6a, 6b, 6c, 6d, and 6e.

As shown in FIG. 13(A) for instance, in the case in which a cross sectional shape that is configured by two divided parts is modified from a square shape to a rectangular shape for the light pipes 6a, 6b, 6c, 6d, and 6e that form a light source in a rectangular shape, a width T in a radial direction or a width S in an axial direction can be modified. Moreover, a width T in a radial direction or a width S in an axial direction can also be modified by adjusting a junction location of the divided parts that are adjacent to each other as shown in FIG. 13(B).

Consequently, since a size of a width T in a radial direction can be arbitrarily modified in accordance with a size of a diameter of the material 4 in a rod shape, an intensity distribution of a laser light in a radial direction can be uniformed regardless of a size of a diameter of the material 4 in a rod shape.

Moreover, in the case in which a width T in a radial direction of a laser light is made larger than a diameter of the material 4 in a rod shape, a fluctuation of a heating intensity distribution does not occur in a range of a width of a laser beam spot 26 even if a central axis of the material 4 in a rod shape is shifted from an axis of rotation to right and left, whereby a crystal can be easily grown. For a conventional lamp heating system or a publicly known laser heating system, a tolerance is small to a shift of a central axis of the material from an axis of rotation, and a temperature falling occurs unfortunately even if a slight shift occurs. By using a system in accordance with the present invention in an effective and efficient manner, an accurate alignment is not necessary. In addition, since a width S in an axial direction of a laser light shown in FIG. 2 can be varied, the raw material rod 14 can be prevented from being in contact with a crystal inside the melting zone 18 during a crystal growth, and a width S in an axial direction of a laser light can be adjusted to be a length that is suitable for a surface tension of the melting zone 18, whereby a spill of a melt can be prevented.

A single crystal of a lanthanum copper oxide La₂CuO₄ was grown by using a laser furnace in accordance with an embodiment of the present invention and a halogen lamp furnace as a comparison example as a practical matter and a difference between the case of the laser furnace and the case of the halogen lamp furnace was researched. The detailed descriptions will be carried out in the following with a focus on a preprocessing and a crystal growth.

In the first place, a preprocessing using a laser furnace in accordance with an embodiment of the present invention will be described in the following.

La₂O₃ and CuO are weighed at a mole ratio of 1:1, and mixed up and pulverized until they become in a uniform powder state in a mortar. They are then put into a container made of alumina and are heated at 1000° C. They are then molded by a rubber press with a hydrostatic pressure and are sintered at 1260° C. to be made to be a cylindrical rod of a diameter of 5 mm. A cylindrical rod of a length of 60 mm and a cylindrical rod of a length of 30 mm are then cut and prepared. The former is used as the raw material rod 14 and the latter is used as the seed crystal rod 16.

Moreover, La₂O₃ and CuO are weighed at a mole ratio of 15:85, and mixed up and pulverized until they become in a powder state in a mortar. They are then put into a container made of alumina and are heated at 900° C. They are then molded by a rubber press with a hydrostatic pressure and are sintered at 900° C. to be used as a solvent (a melting agent). This solvent of 0.34 g is fixed to the upper end part of the seed crystal rod 16.

A single crystal growth chamber is formed by a transparent quartz tube in a space in which the raw material rod 14 and the seed crystal rod 16 are disposed. The single crystal growth chamber is filled with an oxygen gas that is suitable for growing a crystal at 3 atmosphere pressure (a differential pressure: 0.2 MPa). The melting zone 18 can be formed in a stable manner at a laser output of 138 W, at the speed 29 rpm of rotation of the upper crystal driving shaft 8 and the lower crystal driving shaft 12, at a speed 0.60 mm/hr of movement of the upper crystal driving shaft 8, and at a shaft speed of 1.00 mm/hr of the lower crystal driving shaft 12. For the last time, a single crystal is grown at a shaft speed of 0.80 mm/hr.

In the next place, a case of a halogen lamp furnace as a comparison example 1 will be described in the following with reference to FIG. 3. A preprocessing using a halogen lamp furnace in accordance with the comparison example 1 will be described in the following.

La₂O₃ and CuO are weighed at a mole ratio of 1:1, and mixed up and pulverized until they become in a uniform powder state in a mortar. They are then put into a container made of alumina and are heated at 1000° C. They are then molded by a rubber press with a hydrostatic pressure and are sintered at 1260° C. to be made to be a cylindrical rod of a diameter of 5 mm. A cylindrical rod of a length of 9 mm and a cylindrical rod of a length of 9 mm are then cut and prepared. The former is used as the raw material rod 14 and the latter is used as the seed crystal rod 16.

Moreover, La₂O₃ and CuO are weighed at a mole ratio of 15:85, and mixed up and pulverized until they become in a powder state in a mortar. They are then put into a container made of alumina and are heated at 900° C. They are then molded by a rubber press with a hydrostatic pressure and are sintered at 900° C. to be used as a solvent. This solvent of 0.27 g is fixed to the upper end part of the seed crystal rod 16.

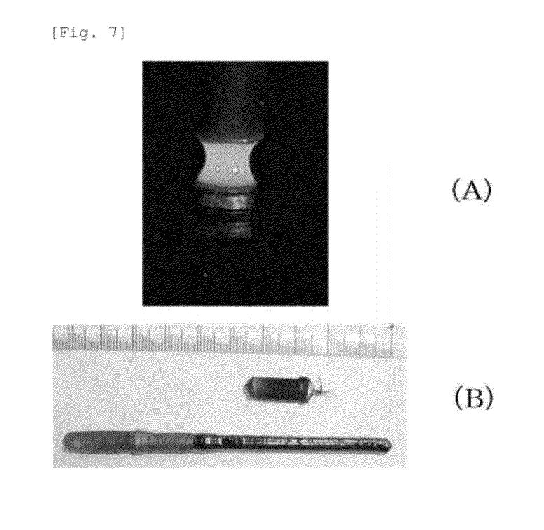

A single crystal growth chamber is formed by a transparent quartz tube in a space in which a raw material rod 14 and a seed crystal rod 16 are disposed. The single crystal growth chamber is filled with an oxygen gas that is suitable for growing a crystal at 3 atmosphere pressure (a differential pressure: 0.2 MPa). The melting zone 18 can be formed at a halogen lamp output in the range of 618 W to 686 W, at a speed 30 rpm of rotation of the upper crystal driving shaft 8 and the lower crystal driving shaft 12, and at a speed 2 mm/hr of movement of the both axes. FIG. 7(A) is a photograph of a melting zone in the case in which a laser furnace in accordance with an embodiment of the present invention is adopted. FIG. 7(B) is a photograph of the grown crystal rod.

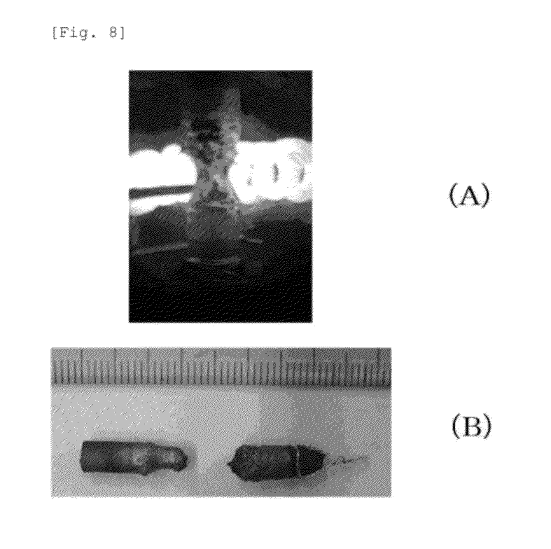

FIG. 8(A) is a photograph of a melting zone 18 in the case in which a conventional halogen lamp furnace is adopted. FIG. 8(B) is a photograph of the grown crystal rod.

As clarified in FIG. 7(A) and FIG. 7(B), in the case of the laser furnace in accordance with the present invention, a boundary of the melting zone 18, the raw material rod 14, and the seed crystal rod 16 is clear, a penetration to the raw material rod 14 can be extremely reduced, and a melt does not spill out from the raw material rod 14 to a solid part, whereby it is confirmed that a good quality of a single crystal can be stably grown at a constant diameter.

On the other hand, as shown in FIG. 8(A) and FIG. 8(B), it is confirmed that a penetration to the raw material rod 14 extremely occurs and a melt extremely spills out onto the seed crystal rod 16 in the case of a conventional halogen lamp furnace.

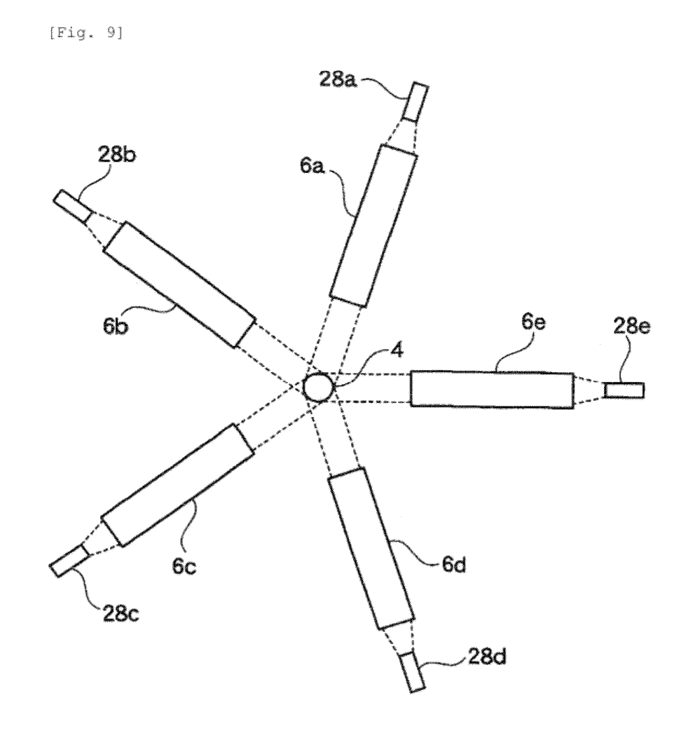

FIG. 9 is a schematic plan view showing a device for a single-crystal growth in accordance with another embodiment of the present invention. Here, elements equivalent to those illustrated in the above embodiment are numerically numbered similarly and the detailed descriptions of the equivalent elements are omitted.

This another embodiment adopts array semiconductor lasers 28a, 28b, 28c, 28d, and 28e as a laser light source. For the array semiconductor lasers 28a, 28b, 28c, 28d, and 28e, 33 elements are arranged in an array pattern in 1 mm in a horizontal direction. A laser light from each element is provided with an intensity distribution of Gaussian distribution at a wavelength of 975 nm, a standard deviation of a spread angle in a horizontal direction is approximately 3 degrees, and a standard deviation of a spread angle in a vertical direction is approximately 10 degrees.

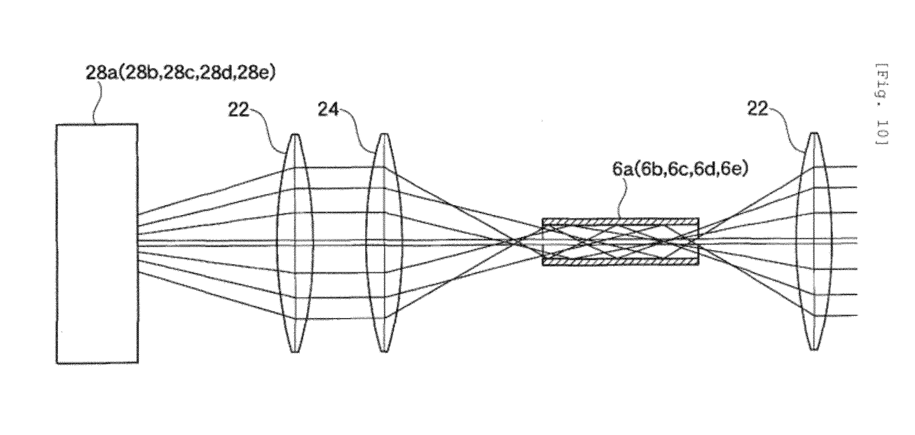

The elements of the array semiconductor lasers 28a, 28b, 28c, 28d, and 28e shown in FIG. 10 are configured by laser diodes not shown.

In this another embodiment, a collimated lens 22 and a light collecting lens 24 are disposed between the array semiconductor lasers 28a, 28b, 28c, 28d, and 28e and the light pipes 6a, 6b, 6c, 6d, and 6e, and a collimated lens 22 is disposed between the light pipes 6a, 6b, 6c, 6d, and 6e and a material in a rod shape not shown.

In this another embodiment, a laser light that has been emitted from the array semiconductor lasers 28a, 28b, 28c, 28d, and 28e that are configured by laser diodes becomes a parallel light at the collimated lens 22, are collected at the light collecting lens 24, and are then introduced to the light pipes 6a, 6b, 6c, 6d, and 6e. A laser light that has been emitted from the array semiconductor lasers 28a, 28b, 28c, 28d, and 28e is reflected in a repeated manner inside the light pipes 6a, 6b, 6c, 6d, and 6e in a rectangular shape to be uniformed to be in a rectangular shape. The laser light that has been emitted from the light pipes 6a, 6b, 6c, 6d, and 6e then spreads in a radial fashion, is made parallel at the collimated lens 22, and is collected in a rectangular shape to a material 4 in a rod shape by a light collecting lens not shown.

Even in this another embodiment, a size of a width S in an axial direction and a size of a width T in a radial direction for the melting zone 18 can be arbitrarily modified in accordance with a size of a diameter of a material in a rod shape similarly to the above embodiment. Consequently, an intensity distribution of a laser light in a radial direction can be uniformed regardless of a size of a diameter of a material 4 in a rod shape.

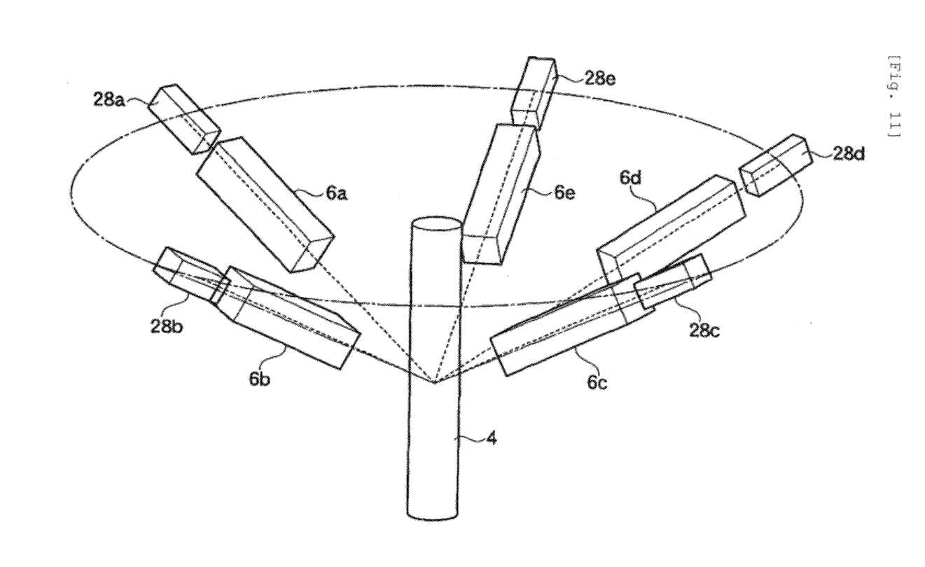

FIG. 11 is a schematic perspective view showing a substantial part of a device in accordance with another embodiment of the present invention.

In this another embodiment, the material 4 in a rod shape is irradiated at an elevation angle with a laser light of the array semiconductor lasers 28a, 28b, 28c, 28d, and 28e that have been arranged in a circumferential direction of the upper crystal driving shaft 8 and the lower crystal driving shaft 12 that are not shown in FIG. 11.

In this another embodiment, the laser intensity distribution of a laser light in a circumferential direction can be uniformed and a rising part 9a and a falling part 9b in the axial direction shown in FIG. 2 can be made steep similarly to the above embodiment. As a result, a penetration to a solid part can be extremely reduced and a melt does not spill out onto a solid part, whereby a good quality of a single crystal can be grown. In addition, a size of a width S in an axial direction and a size of a width T in a radial direction for the melting zone 18 can be arbitrarily modified in accordance with a size of a diameter of a material in a rod shape similarly to the above embodiment. Consequently, an intensity distribution of a laser light in a radial direction can be uniformed regardless of a size of a diameter of a material 4 in a rod shape.

While the preferred embodiments in accordance with the present invention have been described above, the present invention is not restricted to the embodiments. For instance, although a semiconductor laser is used as a laser light source in the above embodiments, the present invention can also be applied to a laser of other types that includes a solid laser.

In the present invention, the raw material rod 14 can be fixed to the lower crystal driving shaft 12, the seed crystal rod 16 can be fixed to the upper crystal driving shaft 8, and a crystal can be pulled up. In addition, an up-and-down motion of a heating means composed of a laser light source and an optical means can also be used, and an up-and-down motion of the upper crystal driving shaft and the lower crystal driving shaft can also be combined to the above embodiments. Moreover, although using of a seed crystal is ideal, a polycrystalline material can also be used as substitute for the seed crystal.

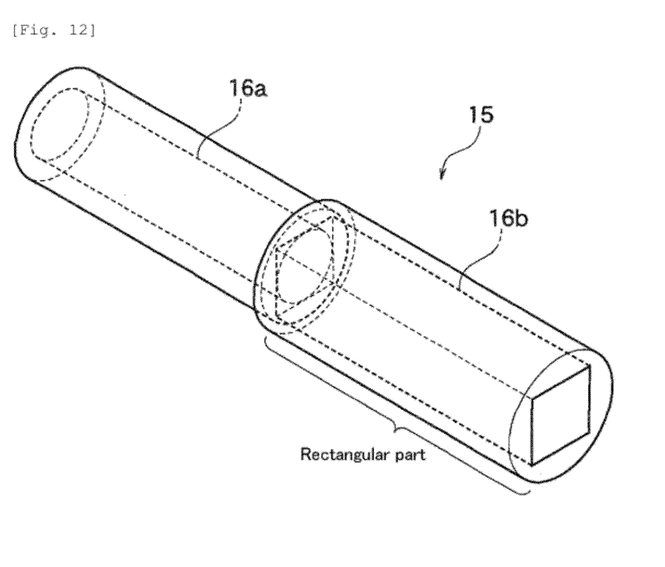

Moreover, an optical fiber 15 shown in FIG. 12 can also be used as substitute for the light pipes 6a, 6b, 6c, 6d, and 6e.

As shown in FIG. 12, the optical fiber 15 is provided with a configuration in which a rectangular core 16b is connected to a circular core 16a inside. An output end face of the rectangular core 16b is formed in a rectangular shape. A laser light that has been transmitted via the circular core 16a is reflected in a repeated manner inside the rectangular core 16b to be uniformed to be in a rectangular shape.

Even in the case in which the entire region inside the optical fiber 15 is a rectangular core, a laser light is formed to be in a rectangular shape similarly.

### INDUSTRIAL APPLICABILITY

The present invention is not restricted to the growth of a single crystal, and can also be applied to a heating, a melting, and a welding of a material in a rod shape.

### REFERENCE SIGNS LIST

2a, 2b, 2c, 2d, and 2e: Fiber coupling semiconductor lasers
4: Material in a rod shape
6a, 6b, 6c, 6d, and 6e; Light pipes
8: Upper crystal driving shaft
9a: Rising part
9b: Falling part
10: Device for a single-crystal growth
12: Lower crystal driving shaft
14: Raw material rod
15: Optical fiber
16: Seed crystal rod
16a: Circular core
16b: Rectangular core
18: Melting zone
20: Optical fiber
22: Collimated lens
24: Light collecting lens
26: Laser beam spot
28a, 28b, 28c, 28d, and 28e: Array semiconductor lasers
S: Width in an axial direction
T: Width in a radial direction

1. A device for a single-crystal growth that is provided with a raw material rod that is supported by an upper crystal driving shaft, a seed crystal rod that is supported by a lower crystal driving shaft, and a heating means that is configured to heat a contact part of the raw material rod with the seed crystal rod, wherein the contact part of the raw material rod with the seed crystal rod is molten with a heating means to form a melting zone that is a single-crystal growth part and to grow a single crystal,
wherein the heating means is configured by a plurality of laser light sources that emit a laser light having the equivalent irradiation intensity and a plurality of optical means that are disposed in connection to the laser light sources and that irradiate the melting zone with a laser light that has been emitted from the laser light source and is disposed in a circumferential direction of the melting zone, and
the optical means is configured in such a manner that a spot shape of the laser light to the melting zone is in a rectangular shape in which a laser intensity distribution in a radial direction and in an axial direction for the melting zone is generally uniform.

2. A device for a single-crystal growth as defined in claim 1, wherein the optical means is configured in such a manner that a width in a radial direction and in an axial direction of the melting zone that is formed in a rectangular shape for the laser light can be arbitrarily varied in accordance with a variation of a diameter of the raw material rod or the seed crystal rod.

3. A device for a single-crystal growth as defined in claim 1, wherein the laser light source is a laser diode.

4. A device for a single-crystal growth as defined in claim 1, wherein a homogenizer which makes an emitted light intensity uniform is used as the optical means.

5. A device for a single-crystal growth as defined in claim 4, wherein a light pipe is used as the optical means.

6. A device for a single-crystal growth as defined in claim 4, wherein a rectangular fiber is used as the optical means.

7. A device for a single-crystal growth as defined in claim 1, wherein the laser light sources of an odd number are disposed.

8. A device for a single-crystal growth as defined in claim 7, wherein the laser light sources of an odd number equal to or larger than 3 are disposed.

9. A method of a single-crystal growth in which a contact part of a raw material rod that is supported by an upper crystal driving shaft with a seed crystal rod that is supported by a lower crystal driving shaft is heated and molten to form a melting zone that is a single-crystal growth part and to grow a single crystal, wherein:
a laser intensity distribution in a radial direction and in an axial direction for the melting zone is in a generally uniform rectangular shape, and the melting zone is irradiated from a circumferential direction of the melting zone with a plurality of laser lights having the equivalent irradiation intensity.

10. A device for a single-crystal growth as defined in claim 2, wherein the laser light source is a laser diode.

11. A device for a single-crystal growth as defined in claim 2, wherein a homogenizer which makes an emitted light intensity uniform is used as the optical means.

12. A device for a single-crystal growth as defined in claim 11, wherein a light pipe is used as the optical means.

13. A device for a single-crystal growth as defined in claim 11, wherein a rectangular fiber is used as the optical means.
